(19) United States
(12) Patent Application Publication
(10) Pub. No.: US 2024/0310721 A1
(43) Pub. Date: Sep. 19, 2024

(54) METHOD AND APPARATUS FOR CALIBRATING AN OPERATION ON A PHOTOMASK

(71) Applicant: Cart Zeiss SMT GmbH, Oberkochen (DE)

(72) Inventor: Michael Budach, Hanau (DE)

(21) Appl. No.: 18/666,889

(22) Filed: May 17, 2024

Related U.S. Application Data
(63) Continuation of application No. PCT/EP2022/082747, filed on Nov. 22, 2022.

(30) Foreign Application Priority Data
Nov. 23, 2021 (DE) 102021213163.8

(51) Int. Cl. G03F 1/74; G03F 1/44; G03F 1/80; G03F 1/84

(52) U.S. Cl. CPC G03F 1/74; G03F 1/44; G03F 1/80; G03F 1/84

(57) ABSTRACT

The present invention relates to a method and an apparatus for calibrating an operation on a mask. A method for producing correction marks on an object for lithography, in particular for calibrating an operation, using a particle beam includes: (a.) producing a first group of correction marks; and (b.) producing a second group of correction marks; (c.) wherein the separations of the correction marks within the first and within the second group are smaller than the separations between correction marks from the first group and correction marks from the second group.

### CROSS-REFERENCE TO RELATED APPLICATIONS

This application is a continuation of and claims priority under 35 U.S.C. § 120 from PCT application PCT/EP2022/082747, filed on Nov. 22, 2022, which claims priority from German patent application DE 10 2021 213 163.8, entitled “Verfahren und Vorrichtung zur Kalibrierung eines Arbeitsvorgangs auf einer Photomaske,” which was filed at the German Patent and Trade Mark Office on Nov. 23, 2021. The entire contents of each of these priority applications are incorporated herein by reference.

### TECHNICAL FIELD

The present invention relates to a method and an apparatus for calibrating an operation on a mask. In particular, the present invention relates to a method for producing correction marks on an object for lithography, to a method for calibrating the operation, and to a corresponding apparatus and computer program for carrying out the methods.

### BACKGROUND

In the semiconductor industry, increasingly smaller structures are produced on a wafer in order to ensure an increase in the integration density. To produce the structures, use is made here, inter alia, of lithographic methods which image the said structures onto the wafer. By way of example, the lithographic methods may comprise photolithography, UV lithography, DUV lithography, EUV lithography, x-ray lithography, nanoimprint lithography, etc. In the process, lithography usually makes use of masks (e.g., photomasks, exposure masks, reticles, stamps in the case of nanoimprint lithography, etc.), which comprise a pattern for imaging the desired structures onto a wafer, for example.

As the integration density increases, so do the demands in respect of the mask production (e.g., as a result of the accompanying reduction in the structure dimensions on the mask or as a result of the greater material requirements in lithography). Consequently, the production processes for masks become increasingly more complex, more time-consuming and more expensive, with it not always being possible to avoid mask errors (e.g., defects). Therefore, the mask errors are usually rectified or repaired in a further processing step.

By way of example, a mask error can be repaired by way of a particle beam-based process, with a corresponding operation being able to comprise processing in a write field and/or a recording of an image in an image field. In the process, the particle beam is usually scanned over the predetermined write or image field in a targeted manner (e.g., along a rectangular pixel raster).

Masks are usually electrically insulating samples, and so scanning the mask with charged particles (e.g., electrons from an electron beam, ions from an ion beam) may cause electrostatic charging of the mask, which inadvertently deflects the particle beam from the intended point of incidence. This effect is referred to as position drift or drift of a particle beam, with other mechanisms also being able to influence this.

The position drift is expressed in the form of displacements, image distortions and/or distortions, which may significantly influence the write or image field of the particle beam defined in advance. To ensure that the particle beam is scanned along a desired work region, it is therefore usually necessary to correct or monitor the particle beam (i.e., a drift correction/drift monitoring must be carried out).

The effects of a relative displacement between the mask and the particle beam are often addressed by defining for example a repair relative to a reference marking in the image or scan region of the particle beam, tracking the position of the reference marking for the repair duration by way of image processing methods, and displacing the particle beam for the repair by use of an offset. However, markings or reference markings degrade in the course of a repair process, since they are subject to similar conditions as the defect to be repaired itself is. Therefore, the markings are scanned as infrequently as possible but as often as necessary.

US 2002/0122992 A has disclosed a method for correcting a photomask, in which a rectangular reference hole is formed in a mask pattern by way of an ion beam. By determining the position of the reference hole, it is possible to calculate a positional relationship between reference hole and a defect in the mask pattern, and this positional relationship is used to correct the defect.

US 2009/0218488 discloses a method and an apparatus for the beam correction of a beam drift. The beam position is aligned using a marker which is sufficiently close to the work region so that it is possible to record an image of the marker without moving a positioning stage. The particle beam is corrected during the processing by using a model that predicts the drift.

However, in particular when repairing or examining large defects or defects having a large area (e.g., greater than approx. 400×400 nm), the known approaches do not always perform to a satisfactory extent.

First, in the case of such large-area defects, the efficiency of the repair process decreases because the adsorption and diffusion processes of the involved process gases behave differently. In a conventional approach, it is additionally necessary even for such large-area defects-since the process time increases as the size of the defect increases—for the reference marks to be scanned more frequently, and as a result they degrade more. A reference mark that is degraded in this way causes greater noise in the position determination and consequently impairs the quality of the repair or even causes the latter to be aborted. Further, the distance of the reference marks from the critical edges (or other relevant structures) of the mask increases. As a result, the accuracy of the edge positioning is decreased because nonlinear influences increase due to the charging.

The present invention is therefore based on the general aspect of specifying methods and apparatuses that provide improved possibilities for examining and/or processing objects (e.g., masks) for lithography, in particular for examining and/or processing large-area defects on such objects (e.g., having a diameter of greater than a few 100 nm).

### SUMMARY

This general aspect is at least partly solved by the various aspects of the present invention.

A first aspect of the invention relates to a method for producing correction marks on an object for lithography (e.g., a mask), in particular for calibrating an operation, using a particle beam. The method may include the following steps: (a.) producing a first group of correction marks; and (b.) producing a second group of correction marks. Here, the separations of the correction marks within the first and within the second group are smaller than the separations between correction marks from the first group and correction marks from the second group. In this case, the first group comprises more than one correction mark, with the second group likewise comprising more than one correction mark.

In this case, a separation between two correction marks arises from the conventional ways of determining the distance between two geometric objects. By way of example, this distance may be defined by way of a length of the shortest connecting line spanned between two points, with each point belonging to a different correction mark. By way of example, a point in this case may comprise a point of an edge of a correction mark (for example, an outer or inner edge of the correction mark) and/or may be any point that can be assigned to the area/geometry of the correction mark. Thus, the correction marks within a group are spaced apart from one another (e.g., arranged next to one another), to be precise in such a way that these are always closer to one another than to the correction marks of the respective other group.

In this case, the separations of the correction marks within a group can be referred to as internal group separations while the separations between correction marks from the first and the second group can be referred to as external group separations. In this case, the internal group separations comprise all possible separations of the correction marks within a group. The external group separations comprise all possible separations between any (desired) correction mark from the first group and any (desired) correction mark from the second group. Accordingly, no internal group separation should be greater than an external group separation.

Known methods for producing correction marks on a mask have previously not relied on this type of geometric arrangement of correction marks. Therefore, operations on the mask that require correction marks for certain purposes could only be carried out previously with a number of disadvantages. In this case, an operation may comprise, for example, (particle beam-based) processing of the mask, examining the mask (e.g., by way of an electron beam of a scanning electron microscope, by way of an ion beam, etc.), locating a work region, calibrating a particle beam, etc.

In particular, the optimized arrangement of the correction marks may serve to determine the position drift of a particle beam in improved fashion and consequently allow an optimized examination and/or repair of errors on the mask (e.g., mask defects). Mask errors represent deviations of the mask from corresponding target values and may arise during the mask production, for example. Typical mask defects are sites or regions in which too much or too little absorber material is present and which are rectified for example by local etching or material deposition with the aid of a particle beam while corresponding precursor gases are introduced.

In particular, a plurality of marks are provided locally in this way (in the form of the first or second group), and so the calibration can be implemented on the basis of a plurality of marks. Thus, once a mark of the first (second) group is worn out, for example, it is possible to alternatively resort to a further mark of the first (second) group, which is arranged in the vicinity and thus can be used for the further calibration of an operation that extends over a relatively long period of time (e.g., when processing and/or imaging a relatively large defect). Alternatively, the marks of a group may also be used in alternating fashion, for example in order to distribute the wear over a plurality of marks and thus maintain all marks for as long as possible.

By way of example, the particle beam can be a beam of particles with mass (e.g., electron or ion beam) or else a massless particle beam (e.g., photon beam).

Optimized operations which are made possible by the production of the groups according to the invention are explained in more detail in the second aspect of the invention.

In a further example, the first group and/or the second group comprise correction marks with at least partly the same form. For example, it is possible to produce correction marks of similar geometric type (i.e., geometrically similar correction marks) in the two groups, with similar correction marks subsequently being able to be used for the same function within an operation. This concept facilitates the presence of a redundancy and/or a distribution of the appearance of wear, for example should a correction marker become worn out, drop out and/or become technically no longer usable during the operation for technical reasons. In this case, the function of a correction mark may comprise a reference mark for a calibration of an operation, for example a mark for determining a drift of a particle beam, a focusing mark for focusing a particle beam, a locating mark for locating a work region, an alignment mark for aligning an operation (e.g., for aligning the mask for processing), a verification mark for verifying an operation, etc. In this case, both the geometry and the material of a correction mark may be designed to be optimized for the specific function intended to be adopted by the correction mark. In this case, any material that can be attached (additively) to a mask is conceivable as a material (e.g., a metal such as platinum, tungsten, etc. and/or an insulating material), wherein the correction marks may likewise be defined out of the mask material and/or the associated substrate (e.g., a correction mark may be formed from chromium, tantalum nitride, molybdenum silicide, absorber material of the mask, etc.). Conceivable geometries would include, for example, circular, spherical, oval, triangular or rectangular correction markers, but also more complex geometries such as crosses, frames, polygons, etc. By way of example, cruciform correction markers of a group could be designed for a first localization of a work region while circular correction markers of this group could serve for the calibration of an operation.

The correction marks may be arranged next to one another in a further example. By way of example, the correction marks can be attached to the mask in a row and/or in the style of an array (e.g., in a field with a plurality of adjacent rows of correction marks). In another example, only geometrically similar correction marks are produced in the first group and/or the second group, wherein the similar correction marks could be used for a plurality of functions in an operation.

In a further example, at least one correction mark from the first group and/or the second group is composed of a plurality of geometric shapes. For example, a correction mark may be composed from a multiplicity of discrete, geometrically similar shapes (e.g., from identical circular/spherical points), which for example are produced very tightly next to one another, and thus a correction mark is formed. By way of example, production can be implemented such that at a certain magnification, which is required for example to read the correction mark by way of image processing, the impression of a uniform contiguous correction mark arises by way of the (e.g., very small) dimensioned discrete shapes. The procedure according to the invention of producing a correction mark from a plurality of discrete shapes may be advantageous from a process-technical view in relation to the processing of a lithography mask. Firstly, optimized process management arises in this type of production for the correction mark since the variability of the process conditions (and hence the susceptibility to errors) can be minimized. This is because the production of a correction mark can be obtained by way of a multiplicity of similar (discrete) individual processes, with for example each individual process producing the same geometric shape on the mask and hence largely requiring the same process parameters. Only the position on the mask where the same geometric shape should be applied needs to be adapted for each step. This leads to a reduction in process complexity, minimization of process variations and increase in process stability, as a result of which it is possible to produce correction marks which reliably have the same properties on the mask over a relatively long production period of time. This ensures reliable functioning of the correction mark for an operation which is based on the correction mark, for example. Furthermore, a multiplicity of discrete geometric shapes enables a simplification of the process of removing the correction marks, since a smaller area of the correction mark is connected to the mask. Additionally, removal can be easier since gaps with mask material, for example, are exposed as a result of the multiplicity of discrete connection areas of the plurality of geometry shapes to the mask within a correction mark. The removal process (e.g., cleaning by way of a wet-chemical process, a plasma process, etc.) can therefore act more uniformly on the correction mark, for example, since even edges of the geometric shapes within a correction mark can be attacked homogeneously. Hence, residues following the removal process can be minimized.

In a further example, a correction mark may be composed of a multiplicity of more complex geometric shapes, which are not necessarily geometrically similar. By way of example, a rectangle in a frame, a circular structure in a circular frame, a reticle, etc. would be conceivable in this case. For example, this would allow the creation of correction mark shapes that are required for specific image processing methods.

In an example, the number of correction marks from the first group and/or the second group is at least three, preferably at least four. This is particularly advantageous as this provides suitable redundancy and/or a suitable wear distribution for, e.g., an operation which is based on the correction marks. In this case, the number of correction marks may be optimized for the operation based thereon so that as many correction marks as necessary but as few correction marks as possible are produced. This avoids the unnecessary production of correction marks, for example to minimize residues during the removal.

In an example, the separations of the correction marks within the first and/or within the second group are at least five times smaller, preferably at least ten times smaller, particularly preferably at least twenty times smaller than the separations between correction marks from the first group and correction marks from the second group. As a result of the aforementioned orders of magnitude of the differences in separation, there can be for example a quick group assignment of two correction marks during an operation. A work region of an operation based on the correction marks may be located, for example, within a region spanned by the separations between correction marks from the first group and correction marks from the second group (i.e., by the external group separations). In this case, the properties of the correction marks may vary depending on the chosen or produced dimensions of the external group separations, for example to optimize a readout of the correction marks. By way of example, if the separations of the correction marks within a group (i.e., the internal group separations) are at least twenty times smaller than the external group separations, the groups could have corresponding large-area correction marks. By contrast, if the internal group separations are five times smaller than the external group separations, the groups could have for example correction marks with a smaller area in comparison therewith. It would likewise be conceivable for the type of correction marks (e.g., the material thereof, geometric shape, etc., as explained above) to be chosen and produced depending on the dimension of the external group separations.

In an example, the production of the correction marks is at least partially based on a particle beam induced deposition process and/or a particle beam induced etching process. In this context, the particle beam induced deposition process may for example comprise an electron beam induced and/or an ion beam induced deposition process. By way of example, the deposition process may be based on vapor deposition (e.g., chemical and/or physical vapor deposition), which is induced or supported by the particle beam in targeted fashion. In this case, it is possible, for example, to locally deposit any desired geometry of a correction mark made of an appropriate material on the mask by use of a targeted guidance of the particle beam and a suitable gas atmosphere. Appropriate methods, which are known to a person skilled in the art, would include for example (focused) electron beam induced deposition ((F)EBID), (focused) ion beam induced deposition ((F)IBID), etc.

The particle beam induced etching process may for example comprise an electron beam induced and/or an ion beam induced etching process. In this context, the etching process may occur for example in an etching environment (e.g., in an etching gas, an etching plasma, etc.), wherein the etching process can be induced or assisted by the particle beam in targeted fashion. By way of example, any desired geometry of a correction mark can be locally etched into the mask material (e.g., the absorber material, the substrate of the mask) by use of a targeted guidance of the particle beam in the etching environment. By way of example, (focused) electron beam induced etching ((F)EBIE) would be an appropriate method.

Further, a particle beam induced (e.g., ion beam induced) milling process may also be used in an example, within the scope of which there is for example local material ablation by way of the guidance of the particle beam. By way of example, ion beam milling would be an appropriate method.

In a further example, the method comprises producing at least one third group of correction marks, the separations of the correction marks within the individual groups being smaller than the separations spanned between correction marks from two different groups. Accordingly, the concept according to the invention is augmented by at least one additional group. The production of at least one fourth group of correction marks and/or an at least fifth group of correction marks, etc., would likewise be conceivable in an example.

In this case, the separations of the correction marks within a group can once again be referred to as internal group separations while the separations between correction marks from two different groups (e.g., between a first and a third group, first and fourth group, fourth and fifth group, etc.) can be referred to as external group separations. In this case, the internal group separations comprise all possible separations of the correction marks within a group. The external group separations comprise all possible separations between (any) two correction marks from two different groups. Accordingly, the concept according to the invention is based on the fact that, even in the case of the plurality of groups (e.g., in the case of three and/or four groups of correction marks), no internal group separation is greater than an external group separation. Four groups, in particular, may be produced in an example. These may be produced in an at least partially quadrilateral arrangement (e.g., in the form of a square or rectangle). The quadrilateral may be arranged around a work region (e.g., a defect), that is to say the (geometric) centroids of the correction marks of the individual groups may form the corners of a quadrilateral that encloses the work region. In another example, the arrangement may for example be implemented in such a way that at least one rectangle made of four correction marks from the four different groups may be formed, within which the work region is located.

The work region can be considered to be the region of the object which is intended to be examined or processed in an operation. By way of example, this may be the region where defect material, for example, is arranged. Within the scope of the present disclosure, the work region can in particular represent a region of the object that is intended to be examined/processed uniformly, that is to say a region that is not examined or processed in a plurality of procedures that can be considered to be independent of one another. The work region of a photomask is in particular a local region that does not encompass the entire photomask. The work region can thus represent or include for example a local defect that does not, for example, break up into a number of completely separate partial defects or can be subdivided into completely separate partial defects. In this case, a “local” defect can mean for example: small in comparison with the size of the object, for example the mask. For example, the work region or the defect contained therein can have one or more lateral extents of less than 1 mm, less than 100 μm, less than 10 μm, less than 2 μm, less than 1 μm, or less than 500 nm. The work region or the local defect could fit, for example, into an (imaginary) square having side lengths of 1 mm, 100 μm, 10 μm or 2 μm or 1 μm or 500 nm.

In this case, the work region can be delimited by a peripheral edge or a contour line, and everything within this edge or within this contour line can be considered to be the work region. In figurative terms, imagine a “lasso” that is thrown for example around a defect and tightened until it has “captured” the defect at the minimum length. The “lasso” then represents the outer edge of the work region (alternatively, one might also consider an elastic band that is thrown around the defect and pulled tight around it, wherein the band would then define, due to its width (e.g., a width of the order of typical diameters of the reference markings discussed here), an edge strip around the work region rather than a linear edge). By way of example, the work region may be defined as an envelope, for example a convex sleeve, of one or more regions to be repaired, with the groups of correction marks being able to be placed such that they enclose the work region.

In a further example, the first group and the second group of correction marks can be produced in such a way that an envelope, for example a convex sleeve, of at least one of the groups of correction marks does not intersect the work region (or in such a way that the convex sleeve of at least one group of correction marks does not represent and/or form a subset of the work region (e.g., of the defect)). By way of example, the groups of correction marks can be placed in such a way that the convex sleeve of the first group and the convex sleeve of the second group do not intersect the work region (e.g., the defect). This may further be interpreted in such a way that the area defined by way of the convex sleeve of a group of correction marks does not form a part of the work region (e.g., the defect).

The rectangular arrangement can be designed as a calibration window for a calibration of an operation, for example for a distortion compensation of a write or image field that is processed using a particle beam. In this case, the rectangular arrangement facilitates, for example, digital data processing or appropriate image processing, which would be required for the distortion compensation.

In a further example, a calibration window can be provided in triangular form (i.e., by way of three produced groups) and/or by way of polygons of different types (i.e., as a m-gon, where m is the number of produced groups).

In a further example, the produced groups surround a work region of an operation in such a way that connecting lines between in each case two correction marks of different groups are able to surround the work region without intersecting the work region. By way of example, the work region may be a mask error (e.g., a mask defect), with no connecting line between two correction marks of different groups intersecting the mask error. Further, this may also be formulated as no connecting line which defines an external group separation intersects the work region. This is advantageous since this for example ensures that the work region is completely surrounded by the groups (and the correction marks located therein). By way of example, this allows a calibration window (e.g., as described above for a distortion compensation) to completely encompass the mask error such that the entire work region can be interpolated over the calibration window without reducing the accuracy of the edge position. Measurement errors which may occur during the determination of the position of the correction marks (and for example may increase the extrapolated region), for example, are not amplified during the distortion compensation as a result.

In a further example of the method, the mask is initially analyzed (e.g., by way of being scanned by a particle beam) in order to find and/or locate a work region on the mask. By way of example, this may comprise the search for a mask error with assistance by image processing (e.g., by way of a method for defect monitoring using pattern recognition). Subsequently, it is possible to attach the groups according to one of the aforementioned examples, with the aid of information about the position of the work region.

In a further example, the method for producing correction marks on an object for lithography may include the following step: producing at least a local group of spaced apart correction marks. By way of example, it is possible to produce exactly one local group of spaced apart correction marks, that is to say it is not mandatory for two groups to be produced. It is conceivable that the correction marks of the local group are produced in a local accumulation, with a dimension of an envelope of the correction marks (e.g., the extent of the correction mark envelope) being of a smaller order of magnitude than a dimension of the envelope of the work region (e.g., shorter). By way of example, the dimension of the envelope of the correction marks of the exactly one local group may be smaller than the dimension of the envelope of the work region by at least a factor of four, preferably by at least a factor of ten, most preferably by at least a factor of twenty. In a further example, the convex sleeve of the local group of correction marks does not intersect the work region (or, for example, the convex sleeve is not a subset of the work region of the operation). In this case, the separations of the correction marks in the local group may be designed in such a way that they are advantageous for the second aspect of the invention (more of this in a moment). Even if only the production of one local group is envisaged, this method may be combined with the further steps described herein. However, independently thereof, it is also possible to produce two or more local groups.

A second aspect of the invention relates to a method for calibrating an operation on an object for lithography (e.g., a mask) with the aid of at least one local group of spaced apart correction marks using a particle beam, the method including the following sequence: (S1.) selecting a sequence tuple, the sequence tuple comprising a subset of correction marks of the at least one group; (S2.) carrying out a calibration, at least partially based on the sequence tuple; (S3.) carrying out at least a part of the operation, at least partially based on the carried out calibration.

By way of example, the second aspect of the invention may at least partially be based on the fact that the at least one local group is a group that was produced according to any one of the aforementioned examples (i.e., a group that was produced in accordance with the first aspect of the invention). In an example, the second aspect of the invention may comprise the first aspect of the invention (or, for example, the first aspect of the invention may also comprise the second aspect). By way of example, the method of the second aspect of the invention may comprise the correction marks being produced (or having been produced) according to the first aspect of the invention. It is likewise conceivable that structures on the mask (e.g., one or more prominent points, structure transitions, various lithography marks, etc.) (naturally) present can be used as local group of correction marks.

The at least one group is local, and so it is arranged on the mask in a spatially delimited region. The spatial delimitation or extent may be provided, for example, by way of the envelope around the external contours of the correction marks of the at least one local group. In this case, the spatial delimitation may be associated with the spatial extent of the operation (e.g., the at least one local group of correction marks may be extended to such an extent as is technically sensible for the operation). Further, the spatial extent of the local group may be restricted to, e.g., a contiguous area, with the following area dimensions being possible: no more than 30 nm×30 nm (or no more than 9×10⁻¹⁶ m²), no more than 100 nm×100 nm (or no more than 10⁻¹⁴ m²) and/or no more than 1 mm×1 mm (or no more than 10⁻⁶ m²). Moreover, the spatial extent of the local group may be defined, for example, by way of a proportion of the area in relation to the overall area A_{M} of the mask. By way of example, the spatial extent of the local group may be no more than 10⁻¹⁴×A_{M}, no more than 10⁻¹²×A_{M}, no more than 10⁻⁹×A_{M} and/or no more than 10⁻⁶×A_{M}. By way of example, the aforementioned spatial extents may also apply to the produced groups which were explained in the context of the first aspect of the invention. A local group may also be distinguished in that a dimension of an envelope of the correction marks (e.g., the perimeter of an envelope around the correction marks) is of a smaller order of magnitude than a dimension of an envelope of the work region. By way of example, the dimension of the envelope of the correction marks of the local group may be smaller than the dimension of the envelope of the work region by at least a factor of four, preferably by at least a factor of ten, most preferably by at least a factor of twenty.

In this case, the sequence of the method according to the invention may be repeated multiple times within the scope of an overall operation. Thus, the calibration may be carried out for different parts of the operation (i.e., sequence operations) in order to ensure stable parameters during an operation (i.e., in a sequence). The (overall) operation in this case comprises overall (i.e., self-contained) processing of the mask while the part of the operation may be a partial step of the (overall) operation. In this case, the operation may comprise a particle beam-based procedure, with for example a recording of an image of an image field or a processing of a write field using a particle beam being conceivable. In this case, the recording of the image may comprise for example a recording by way of a scanning electron microscope while the processing of the write field may comprise a particle beam induced etching or deposition process. In this case, a work region may comprise the write or image field. By way of example, the calibration can be used to calibrate or correct the parameters of the particle beam for the operation.

To date, addressing the calibration of the particle beam has been known to involve, for example, defining the operation relative to one and the same correction mark. During calibration, an appropriate correction mark is usually scanned using a particle beam (e.g., for a recorded image). However, the corresponding correction mark and its immediate vicinity may significantly degrade over time during the operation or overall operation, which may increasingly lead to a worsening calibration. This is because the correction mark during the calibration may be exposed to the same process influences of the operation (e.g., the states of a particle beam induced deposition or etching process are still present). A disadvantage of the previously known procedures is that, in particular, a continuously reliable calibration is limited, inter alia, by the processing duration of the operation. In the case of a longer processing duration (e.g., in the case of relatively large work regions, work regions that are only able to be processed slowly, complex work regions, etc.), it is usually necessary to carry out a calibration more frequently, and so the correction mark and its surroundings may degrade to a substantially greater extent. The accuracy with which the position of the correction mark is determined by the image processing may reduce significantly over time (e.g., as a result of a reduced contrast, the correction mark appearing washed out, etc.). Additionally, permanent damage (e.g., a defect) may remain on the mask following the operation on account of the degradation of the surroundings of the correction mark.

The concept according to the invention remedies the known disadvantages by virtue of a sequence tuple comprising a subset of correction marks from a group of correction marks being selected for each sequence. This subset can subsequently be used for the calibration within the sequence. The calibration of a sequence accordingly is based on a targeted selection of a subset of correction marks, which was selected in view of an optimal calibration. In this case, the subset may comprise at least one correction mark (however, a plurality of correction marks from a group, for example, is also conceivable). Consequently, it is given that a selection of suitable correction marks (or one correction mark) is possible for a sequence. Consequently, it is not necessary to resort to a fixed correction mark for the calibration, which correction mark may for example already be significantly degraded, but it is possible to use a subset of correction marks that works well for the calibration. This ensures that the operation (part of the operation) which is based on the calibration can be carried out optimally and/or without bothersome influences since an incorrect calibration of the operation is avoided.

In an example, the selection of the sequence tuple is at least partially based on an assessment of a predetermined criterion which is associated with at least one correction mark of the at least one group. In this case, the predetermined criterion may provide an indication for the degree of degradation of the correction mark or may be designed so that the degree of degradation is minimized. By way of example, the criterion may comprise the number of times a correction mark (or a sequence tuple) was used during the method (which may correspond to an estimate for the degree of wear of the mark). In particular, it is possible to assess how often a sequence tuple was selected in succession. In a further example, the criterion may be assessed by way of a physical analysis (e.g., by way of recording an image of the correction mark using a particle beam).

In an example, the predetermined criterion comprises at least one of the following criteria: a degree of wear of the at least one correction mark, a contrast of the at least one correction mark, a gradient image of the at least one correction mark, an autocorrelation function of an image of the at least one correction mark, a cross-correlation function of at least two images of the at least one correction mark.

By way of example, the aforementioned criteria could be determined on the basis of a recorded image of the correction mark (e.g., a scanning electron image) (or the criterion could be determined on the basis of a fundamental signal produced by scanning the correction mark using a particle beam). By way of example, the degree of wear can be measured or assessed automatically by way of image processing (and/or manually by an operator). By way of example, the gradient image may be obtained by way of (digital) processing of the image of the correction mark (or of the fundamental signal) and may comprise information about the edges of the correction mark. By way of example, this allows a good assessment of the degradation of the edges, which may become flatter with time. Likewise, the nature of the autocorrelation function of a correction mark can be determined from the image of the correction mark (or from the fundamental signal). By way of example, in this case a broader autocorrelation function may be associated with a higher degree of degradation, and so a corresponding correction mark might no longer be used for a calibration above a given threshold value. Moreover, there may be a cross-correlation function of the correction mark, which is based on images of the correction mark (or the fundamental signal) at two different times (e.g., from two different sequences). Hence, a relative change in the correction mark can be assessed analytically.

In a further example, the sequence is repeated at least once and, in the process, at least two sequence tuples are selected, the sequence tuples comprising differing subsets of correction marks. For the overall operation (which comprises at least two sequences, for example), it is consequently not necessary to continuously use one and the same correction mark for the calibration. This may significantly minimize both the appearance of degradation of the correction marks and the mask damage caused by the calibration since it is not necessary for all correction marks (or always the same correction marks) to be exposed to the particle beam for every sequence. This ensures reliable operation of the calibration even for relatively long processing times, which for example arise in the case of a great number of sequences.

In an example, the sequence tuple is selected in such a way that it comprises a subset of correction marks from each of at least m groups of correction marks, where m is greater than or equal to 2 (e.g., m=4), and the separations of the correction marks within the individual groups are smaller than the separations which are spanned between correction marks from two different groups. By way of example, this example may at least be partially based on the at least m groups being groups which were produced in accordance with the first aspect of the invention (and the examples of which were explained above). By way of example, four groups may be arranged on the mask in a rectangle, with each group comprising at least three correction marks, for example. This allows a certain sequence tuple to be chosen for the calibration of the sequence from a multiplicity of possible sequence tuples. By way of example, each tuple may comprise (exactly) one correction mark from each of the m groups.

In an example, the selection of the sequence tuple is at least partially based on a number of expected sequences during the operation. By way of example, this may be based on the number of expected calibrations and/or the expected parts of the operation. The number (of sequences, calibrations and/or parts of the operation) may be determined, inter alia, by analyzing the work region. By way of example, this may comprise the analysis of a mask defect, wherein some parameters of the mask defect, for example an area of the defect, a type of defect, a material of the defect, a mask type, etc., can be observed for determining the number.

In an example, the selection of the sequence tuples over the sequences of the operation is implemented in accordance with a predetermined order. The order may be defined in such a way that appearances of wear (or appearances of degradation) on the correction marks are minimized or uniformly distributed. In this context, a physical analysis of the correction marks (e.g., by assessing an appropriate criterion, as presented in a few examples) may be dispensed with in an example as a result of skillful ordering of sequence tuples. Likewise, an example is conceivable, in which the sequence minimizes (and/or uniformly distributes) the appearances of wear but there is an occasional physical analysis of the correction marks (e.g., by way of recording an image with a subsequent analysis).

In an example, the selection (of the sequence tuples) is implemented in accordance with a cyclical order of sequence tuples, a randomized order of sequence tuples and/or a row of the same sequence tuples. By way of example, a plurality of differing sequence tuples (T1, T2, . . . . Tm) may be available on the mask. In a cyclical order, a certain cycle order of sequence tuples would be “rotated through” over a plurality of sequences of the method. By way of example, if three sequence tuples were available (e.g., T1, T2, T3), an exemplary cycle order would be given by T1-T2-T3, with the corresponding cyclical sequence order over the sequences of the method being T1-T2-T3-T1-T2-T3-T1-T2-T3 . . . etc., for example. In the case of three sequence tuples, the randomized order would comprise a random order of sequence tuples over a plurality of sequences of the method (e.g., T3-T1-T3-T3-T2-T1-T1-T2-T2 . . . etc.).

When selecting the sequence tuples in accordance with a row of the same sequence tuples, an exemplary sequence (in the case of three sequence tuples) could in the process be determined as follows: T1-T1-T1 . . . T2-T2-T2 . . . T3-T3 . . . T3. Especially when selecting the sequence tuples in accordance with a row of the same sequence tuples, there can be an additional assessment of a predetermined criterion (as explained above in exemplary fashion), with this being conceivable in the case of the other orders too. By way of example, an assessment of the predetermined criterion may be carried out after a predetermined number of sequences which used the same sequence tuple, in order to verify the state of the correction marks of the sequence tuple. As appropriate, depending on the state of a correction mark of the sequence tuple, it is possible to change to a different sequence tuple in the following sequence (in order to ensure an optimal calibration) or continue to use the sequence tuple (for example, because there still is no appearance of wear).

In an example, the method further includes the following: determining a transformation of particle beam parameters which is associated with two sequence tuples; carrying out the calibration, at least partially based on the determined transformation. In principle, at least two sequence tuples must be available for this concept, with the specified procedure being implementable accordingly for all possible sequence tuples (for example, if more than two sequence tuples are available).

By way of example, the method may in this case comprise a determination of initial positions of the correction marks of the (possible) sequence tuples which can be selected for the method. In this case, the determination may be carried out before the first sequence of the method, for example. The mask may become electrostatically charged if it (e.g., a correction mark of a sequence tuple) is irradiated using a particle beam within the method. Consequently, there is a disturbance in the system which may influence the desired trajectory of the particle beam. Usually, the desired trajectory can be adjusted both dynamically and statically by way of particle beam parameters (e.g., acceleration voltage, deflection voltage, adjustments to particle beam optics, etc.). As a result of the aforementioned disturbance, the positions of the (possible) sequence tuples may, over the course of the method (e.g., should a further image be recorded by way of a particle beam), appear as if they were displaced in relation to their initial positions. In this case, these “new” positions may be referred to as current positions. In this case, the offset of the (possible) sequence tuples is not necessarily uniform, the correction marks may be displaced independently of one another or appear thus (e.g., on account of different charging). By way of example, the correction marks of a (possible) sequence tuple may initially appear arranged next to one another in a row, such that their centroids form a straight line. However, during the course of the method, the correction marks may become displaced during the recording of an image, in such a way that their centroids no longer form a straight line (e.g., at first sight, each correction mark may appear randomly offset in space). These (e.g., non-linear) effects may influence the calibration of the particle beam in such a way that the previously desired trajectory (e.g., over the work region) is no longer traversed. According to the invention, it is therefore possible to carry out a transformation which, for example, considers the initial position of one (or both) of the two sequence tuples in relation to a current position of this and/or the other one of the two sequence tuples. Accordingly, the transformation can re-establish a correct relationship between two sequence tuples, which is no longer given pictorially as a result of the disturbance in the system. The calibration within the sequence can subsequently additionally consider the information of the transformation such that the particle beam can be calibrated in accordance therewith. This allows the trajectory of the particle beam to be independent of a change in the chosen sequence tuples within the method. This can ensure that the same work region is at least partially traversed by the particle beam. The transformation allows the edge quality of the work region in particular to be optimized since the edges of the work region would not be optimally processed in the case of a missing transformation (e.g., flatter side wall angles may occur in the etched and/or deposited structures).

In an example, the method further includes the following: determining a transformation of particle beam parameters which is associated with the selected sequence tuple and/or the sequence tuple selected in a preceding sequence and/or carrying out the calibration, at least partially based on the determined transformation. By way of example, the transformation may be carried out in the case of each sequence change. In another example, the transformation may be carried out when changing sequence tuples during the method (e.g., when changing the sequence tuple on account of the chosen order, as explained above).

In an example, determining the transformation comprises at least one of the following: determining a relative position of correction marks of different sequence tuples in relation to one another; and/or determining the relative positions of correction marks of different sequence tuples in relation to one or more structures of the object for lithography (e.g., the mask). The relative positions (or position differences) may in this case be defined in the style of vectors (e.g., <x,y>), for example.

By way of example, a relative position between the initial positions of the correction marks of the (possible) sequence tuples may be determined (e.g., in each case between two correction marks of the sequence tuple from different groups). Further, a relative position between the current positions of the correction marks of the (possible) sequence tuples may also be determined. Then, the transformation allowing a change from one sequence tuple to the other and minimizing the aforementioned errors in the process can be determined from the different relative positions. Furthermore, it is also possible to determine the relative position between the initial position of a sequence tuple and the current position of a different sequence tuple. It is likewise possible to determine the relative position between the initial position of a sequence tuple and the current position of this sequence tuple.

Further, the aforementioned determination of the relative positions of the correction marks of various sequence tuples in relation to one or more structures considers at least one third “fixed point,” which comprises the one or more structures (e.g., of the mask). Accordingly, the transformation can be identified by determining the position of a (characteristic) structure relative to the position of a first sequence tuple and determining the (characteristic) structure relative to the position of a second sequence tuple. Hence, for example, there may be a transformation from the first sequence tuple to the second sequence tuple via the third “fixed point.”

In an example, the calibration comprises determining a drift of the particle beam and/or correcting a drift of a particle beam. In this case, the calibration may comprise the determination of an offset which is associated with the determined drift of the particle beam. The offset can subsequently be used for correcting the drift of the particle beam such that the desired trajectory of the particle beam is constant or maintained during the method.

In an example, the operation comprises repairing a defect. In this case, the defect may for example comprise a mask defect, with the defect being able to be processed in such a way by use of a deposition or etching process (as explained in the examples above) that the defect is at least partially repaired. Here, the work region may comprise the defect or be defined by the dimensions thereof (e.g., by way of the contour thereof).

It is emphasized that the first and the second aspect described herein may also be combined with one another. That is to say, the production of correction marks as described herein may be followed by a calibration method as described herein which is aided by the produced correction marks.

A third aspect of the invention relates to an apparatus for producing correction marks on a mask and/or calibrating an operation using a particle beam, comprising: (a.) means for (automatically) carrying out one of the methods described herein; (b.) means for carrying out a computer program. In this case, the apparatus may comprise an apparatus suitable for carrying out particle beam-based processes. In this case, the apparatus may comprise, for example, an electron beam system and/or an ion beam system, which is configured for particle beam induced deposition and/or etching processes. Processing would also be conceivable in a particle beam system which is able to control at least one electron beam and also at least one ion beam in a targeted fashion (e.g., a dual beam system or a cross beam system).

A fourth aspect of the invention relates to a computer program comprising instructions which, when executed, cause the aforementioned apparatus to carry out the method steps according to one of the methods described herein.

A further aspect relates to the aforementioned apparatus with a memory which comprises the computer program. Further, the apparatus may have a means for executing the computer program. Alternatively, it is possible for the computer program to be stored elsewhere (e.g., in a cloud) and for the apparatus to merely have means for receiving instructions that arise from executing the program elsewhere. Either way, this may allow the method to run in automated or autonomous fashion within the apparatus. Consequently, it is also possible to minimize the intervention, for example by an operator, and so it is possible to minimize both the costs and the complexity when processing masks. Moreover, the method may also be present in written form (e.g., in an instruction manual for the aforementioned apparatus), in order for example to communicate targeted instructions with regards to the method procedures to the operator.

### BRIEF DESCRIPTION OF DRAWINGS

The following detailed description describes technical background information and exemplary embodiments of the invention with reference to the figures, in which:

FIG. 1 illustrates an aspect of the problems that arise when examining and/or processing a photolithographic object with an electron beam, wherein the element has a charged surface.

FIG. 2 schematically illustrates a top view of an exemplary repair situation of a defect of a photolithographic mask as described in the prior art.

FIG. 3 schematically shows compensation of a drift of an electron beam with respect to a marking caused by an electrostatic charge, according to the prior art.

FIG. 4 reproduces displacements of a marking with respect to an x-axis and a y-axis during the repair of the defect of FIG. 2.

FIGS. 5A-5C schematically show various aspects of the present invention. FIG. 5A in this case shows an example of correction marks according to the invention for calibrating an operation on a mask. FIG. 5B shows a selection of sequence tuples for an operation. FIG. 5C illustrates the topic of the transformation of particle beam parameters in the present invention.

FIG. 6 finally schematically shows a few components of an apparatus for performing a method according to the invention.

### DETAILED DESCRIPTION

Some technical background information and possible embodiments of methods and apparatuses according to the invention are explained in greater detail below on the basis of the examination of a photolithographic mask and the processing of a defect of a photolithographic mask.

The methods and apparatuses according to the invention can be used initially for examining and/or processing all types of transmissive and reflective photomasks. Furthermore, the methods and apparatuses according to the invention can also be used for examining and/or processing templates for nanoimprint lithography and/or wafers. The methods and apparatuses according to the invention are furthermore not even limited in principle to the examination or processing of (photo)lithographic objects. Rather, they can be used generally for analyzing and/or processing an electrically non-conductive or only poorly conductive sample with a charged particle beam.

To aid clarity and avoid ambiguity, however, the embodiments that follow will involve throughout the example of a photolithographic mask, although the other possible uses of the described invention aspects are always encompassed thereby and should therefore also always be taken into account.

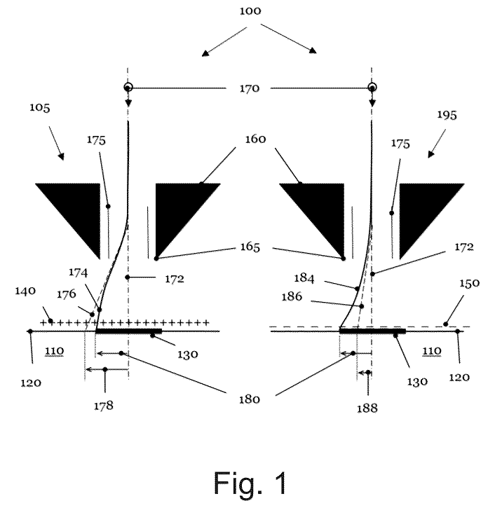

The diagram 100 in FIG. 1 shows a schematic section through a charged mask 110 and an output 165 of a scanning electron microscope 160. The mask 110 has on its surface 120 a distribution of surface charges that cause an electric potential distribution or an electrostatic charging of the mask 110. On the left image part 105, the mask surface 120 has a positive charge 140. In the right image part 195, the mask surface 120 shows an excess of negative charges 150. The reference signs 140 and 150 are used hereinafter to denote both a distribution of surface charges on a mask surface 120 and also the electric potential distributions caused by the charged surfaces.

An electric charge 140, 150 on a mask surface 120 can be caused by a beam of charged particles 170, for example an electron beam 170 of a scanning electron microscope (SEM) 160. An electrostatic charge 140, 150 on a mask surface 120 can be caused by the scanning of the mask 110 as part of an examination process or can arise as a result of a processing process. For example, electrostatic charging can be caused when processing the mask 110 with an electron beam or ion beam. Further, electrostatic charges 140, 150 on a mask 110 can be caused for example by the handling of the mask 110.

In the portion of the mask 110 that is illustrated in the diagram 100 in FIG. 1, the distribution of the surface charges 140, 150 has a uniform density. However, this is not a condition necessary for the explanations made herein.

In the example in FIG. 1, a deflection system 175 deflects the electron beam 170 and scans the latter over the mask surface 120 in order to determine the dimensions of the structure element 130 of the mask 110. By way of example, a structure element 130 can be a pattern element of an absorber structure of the mask.

As is illustrated in the left image part 105 of the diagram 100, as a result of the attractive effect of a positive charge 140 of the mask surface 120, an electron beam 170 scanning the structure element 130 is deflected in the vicinity of the mask surface 120 in the direction of the optical axis 172 and follows the trajectory 174. Without the electric potential distribution 140, the electron beam 170 would follow the path 176. In an SEM image produced by the electron beam 170, the scanned dimension 178 appears larger than the actual dimension 180 of the structure element 130.

By analogy, the right image part 195 in FIG. 1 illustrates the repellent effect of a negatively charged 150 mask surface 120 on the path movement 184 of the electrons 170 of an electron beam 170. Without the electric potential distribution 150, the electron beam 170 would follow the path 186. As a result of the additional deflection of the electron beam 170, which is directed away from the beam axis 172, in the vicinity of the mask surface 120 as a consequence of the electrostatic charge 150, the measured dimension 188 of the structure element 130 in an SEM image generated from the scanning data appears to have a smaller dimension than the actual dimension 180 of the structure element 130.

The scanning of the structure element 130 by use of an electron beam 170 or more generally with the aid of a charged particle beam 170 can result in local heating of the mask 110 and thus in a change in the extent of the mask 110. Even if these changes in the length of a mask 110 are merely of the order of nanometers, these changes should be taken into account in a processing process of a mask 110 in order not to jeopardize the success of the processing process. Moreover, it is possible for thermal effects of the SEM 160 and/or of the mask 110 or the sample mount (not illustrated in FIG. 1) to cause the point of incidence of the electron beam 170 on the mask 110 to drift as a function of time once again in the two-digit nanometer range.

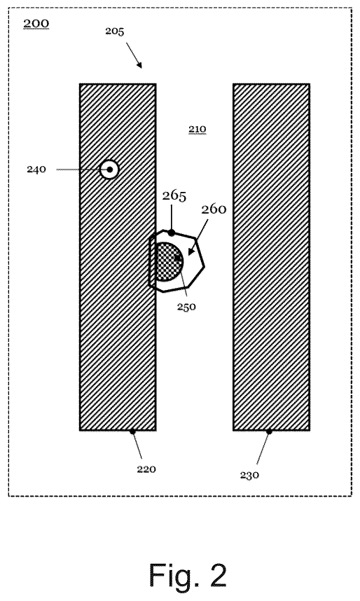

FIG. 2 shows a portion of a top view of a mask 200. This can be the mask 110 in FIG. 1, for example. The photomask 200 comprises a substrate 210. Two pattern elements 220 and 230 in the form of absorbent strips are arranged on the substrate 210 of the mask 200. At the pattern element 220, the mask 200 has a defect 250 in the form of excess material. To correct the defect 250, a marking 240 is applied on the pattern element 220 in the example illustrated in FIG. 2. The marking 240 (which may also be referred to as correction mark) is used to determine and compensate for a drift or a displacement of the electron beam 170 with respect to the defect 250 during a repair process of the defect 250.

The marking 240 is deposited after the identification of the defect 250 on the mask 200 for example with the aid of an electron beam induced deposition (EBID) process, that is to say with the provision of at least one precursor gas or process gas on the mask 200. It is advantageous if the precursor gas(es) are chosen such that the marking 240 has a different material composition to the pattern elements 220, 230 of the mask 200. In the image of an SEM 160, the marking 240 distinguishes itself not only by way of a topology contrast but additionally by way of a material contrast.

To eliminate the defect 250, an etching reaction is triggered due to an electron beam or particle beam at the location of the defect 250 for example with the provision of a further precursor gas or process gas (or gas mixtures), and the defect 250 is removed therewith. In line with this and with the statements made above with respect to the meaning of the term “work region,” the work region 260 in FIG. 2 is defined substantially by the extent of the defect 250 and is bounded or enclosed by the contour line 265. The work region is indicated here in FIG. 2 merely in a highly schematic fashion. However, as can be clearly seen, in the case of FIG. 2, which shows the prior art, the marking 240 lies outside the work region 260.

A material deposition, for example for correcting a clear defect of the mask 200, would be analogously possible.

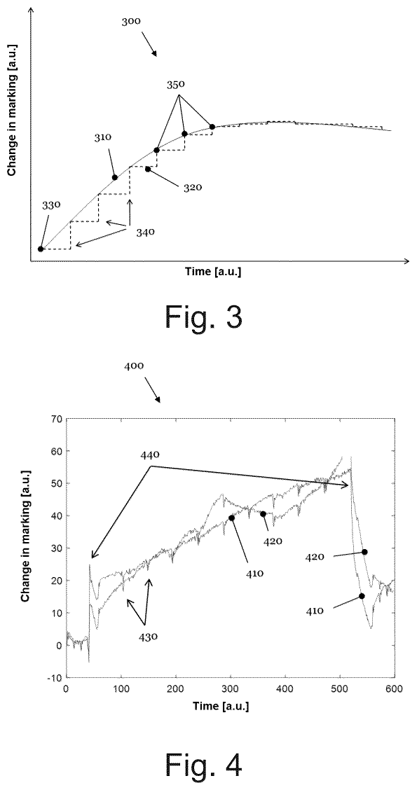

FIG. 3 schematically presents by way of example the compensation of drift or a displacement of an electron beam 170 relative to the marking 240 during a repair process of the defect 250 according to the prior art. Local electrostatic charging of the mask 200 is difficult to define mathematically. This also applies to thermal drift between the electron beam 170 and the marking 240. The effects of electrostatic charging of the mask 200 and/or the displacement thereof relative to the point of incidence of the electron beam 170 are therefore measured and corrected with respect to the marking 240 at periodic intervals of time. The solid curve 310 in FIG. 3 schematically shows the change, displacement, variation or drift of the marking 240 as a function of time during a repair process of the defect 250.

At the beginning of the repair process, a reference position 330 of the marking 240 is determined. The reference position 330 can be specified relative to a reference marking of the mask 200 or in absolute terms with respect to a coordinate system of the mask 220. In the second step, the position of a repair shape is defined with respect to the marking 240. In this case, the repair shape may be designed such that the latter covers the defect 250 within the work region 260. In an example, the repair shape may (at least partially) correspond to the spatial dimensions of the defect 250 (for example, the area, shape and/or contour of the repair shape may correspond to the corresponding properties of the defect 250). In a further example, the repair shape may correspond to the work region 260 (for example, the repair shape may be identical to the work region 260). The examination or processing of the defect 250 may for example be carried out in such a way that the electron beam is scanned along the repair shape and, as a result, carries out or induces the examination or processing of the work region or defect in a manner known per sc. The repair shape may be known in advance, for example from the examination or processing of similar work regions or defects (e.g., work regions or defects with approximately the same size, approximately the same shape, material property, defect class, etc.).

The repair of the defect 250 is then begun. For this purpose, one or more etching gases are provided at the location of the defect 250 of FIG. 2, as already mentioned, and the electron beam 170 is scanned, as specified by the repair shape, over the defect 250 and through the work region 260 schematically shown in FIG. 2.

After specific intervals of time 320 have passed, the repair process is interrupted at regular or irregular intervals of time 340, but without interrupting the provision of the precursor gas(es), in order to scan the marking 240 with the electron beam 170. A displacement, drift or change 350 in the marking with respect to the reference position 330 or relative to the preceding measurement of the marking 240 is determined from the SEM image of the marking 240. Afterwards, the position of the repair shape in relative or absolute terms with respect to the marking 240 is corrected on the basis of the change 350 in the marking and the repair process of the defect 250 is continued.

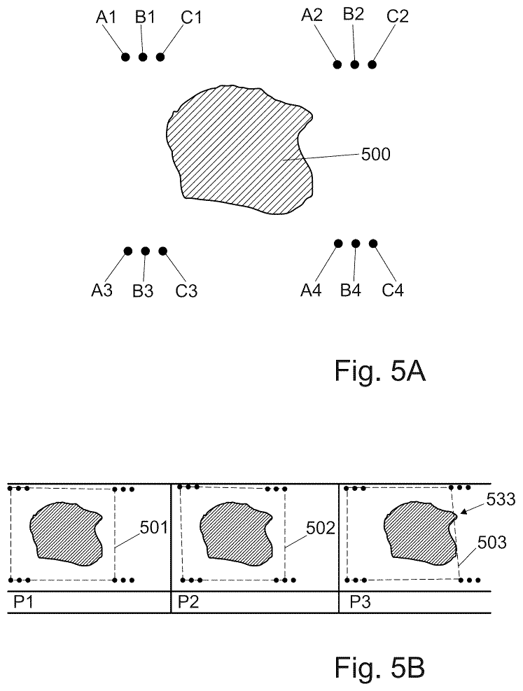

FIG. 4 shows a further example of a displacement or drift of the marking 240 during a repair process of the defect 250 according to the prior art. Time in arbitrary units is plotted on the x-axis of the diagram 400 in FIG. 4. The number of measurements of the marking 240 during a repair process can also be shown on the abscissa of the diagram 400. The interval of time between performing two scanning processes can lie in the range from 1 second to 50 seconds. The example illustrated in FIG. 4 indicates a time range of approximately 1000 seconds. The total displacement or drift of the marking 240 in arbitrary units relative to the reference position 330 of the marking 240 is shown on the y-axis of the diagram 400. By way of example, the drift can be specified as the number of scanned pixels of the electron beam 170 in one direction.

Depending on the focusing of the electron beam, a pixel can have dimensions in the range of 0.1 nm to 10 nm. The ordinate of the diagram 400 encompasses a position change of approximately 120 nm.

The drift of the marking 240 in the x-direction is shown by the curve 410 in the diagram 400 and the displacement of the marking 240 in the y-direction is shown by the curve 420. Large position changes or position displacements of the marking 240 are brought about by switching between two process or precursor gases. This is illustrated by the arrows 440 in FIG. 4. Smaller swings or jumps in the position change are brought about for example by switching between different repair shapes for repairing the defect 250 (see the arrows 430).

The procedure according to the prior art shown in FIGS. 2 to 4 may be adequate for small defects, such as the defect 250 (it should be noted that the extent of the defect 250 is smaller than the dimensions of the lines 220, 230 and spaces between them, that is to say typically a few nm). However, for large-area defects (for example extents of a few 100 nm), the conditions change significantly.

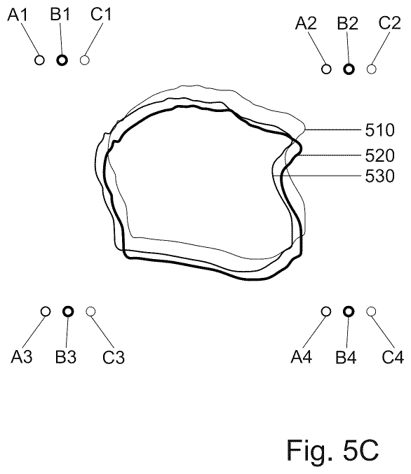

FIGS. 5A-5C schematically show various aspects of the present invention. Proceeding from the situation known from the prior art, it is possible according to the invention to undertake, inter alia, an increase in the accuracy and efficiency of the examination and/or processing of a mask, especially for large-area, contiguous defects.

In this case, FIG. 5A shows an example of correction marks according to the invention (which may also be referred to as markings, reference markings, etc.) for calibrating an operation on a mask, and an associated work region. In this case, the work region 500 may comprise a defect on the mask which should be repaired. The operation may serve to repair the defect on the mask, with a particle beam-based process being conceivable here (e.g., a particle beam induced deposition or etching process). In this context, the work region 500 may initially be located in an initial step. To this end, it is possible to use conventional methods for defect recognition on a mask, for example. By way of example, the mask can be scanned using an electron beam such that a scanning electron image is produced. Image processing can subsequently analyze the scanning electron image in order to locate the defect and additionally define the work region 500. By way of example, the image processing can be part of a method for automated defect control and may comprise a pattern recognition of relevant defects. The work region 500 may be considered to be a write field (i.e., for physical processing of the mask) and/or an image field (i.e., for the purposes of recording an image of the work region).

According to the invention, at least two groups of correction marks can be produced around the work region 500. By way of example, the groups can be produced by way of a particle beam-based process. In this case, particle beam induced deposition or etching processes would be conceivable, for example an electron beam induced deposition, an ion beam induced deposition, an electron beam induced etching, an ion beam induced milling, etc. The deposition or etching may be implemented here on the mask material or the substrate of the mask. The application of particle beam-based processes may allow large degrees of freedom when designing the correction marks in relation to their geometry, their material and their position on the mask. Accordingly, the groups of correction marks around the work region 500 can be designed in various variants. By way of example, the correction mark can have any desired geometry, for example a circular structure, an amalgamation of circular structures lying close together, a polygon, a sphere, a hole, a trench, etc. In this case, the geometry of the correction mark may depend decisively on the chosen deposition or etching process. By way of example, additive topologies may be produced by way of deposition processes while structures can be produced by way of material ablation in an etching procedure. Likewise, the correction mark material may depend on the chosen deposition process or the etching process. By way of example, the material of the correction marks may comprise a metal (e.g., platinum, tungsten, silver, gold, etc.), an insulator (e.g., nitride, oxide, polyimide, etc.), a semiconductor, etc. in a deposition process. Composite materials are also conceivable here. In the case of an etching process, the correction mark material may for example comprise or be defined by way of the material of the mask and/or substrate. By way of example, the correction marks may be defined by way of (etched/milled) holes in an absorber strip of the mask, in a substrate of the mask, etc.

As presented in FIG. 5A, four groups of correction marks, for example, may be arranged around the work region. In this case, the first group may comprise the correction marks A1, B1, C1. The second group may comprise the correction marks A2, B2, C2. The third group may comprise the correction marks A3, B3, C3. The fourth group may comprise the correction marks A4, B4, C4. The groups may each comprise the same number of correction marks (each group has three correction marks in this example), with it also being conceivable that the groups could comprise different numbers of correction marks.

According to the invention, a group is defined by way of a local accumulation of correction marks which are spatially delimited from a different group of correction marks. In this case, the separations of the correction marks within the individual group (i.e., internal group separations) may be smaller than the separations which are spanned between correction marks from two different groups (i.e., external group separations). By way of example, the following separations between the correction marks arise within the first group: A1B1 (from correction mark A1 to B1), A1C1 (from correction mark A1 to C1), B1C1 (from correction mark B1 to C1). In this case, the separations may be determined, for example, by way of the centroids, the edges, any surface points, etc. of the correction marks. Separations between correction marks from two different groups are for example: A1A3 (from correction mark A1 to A3), C1A2 (from correction mark C1 to A2), A1C4 (from correction mark A1 to C4). As is evident from FIG. 5A, no separation between correction marks from two different groups is smaller than a separation (any separation) of correction marks within a single group (e.g., A1A3>A1C1).

The groups arranged in this way may serve to optimize the operation for processing the mask or for processing the work region of the mask. As described in relation to FIG. 3, a calibration with the aid of a marking (or correction mark) must be carried out usually multiple times for an operation while the mask is being processed. By way of example, this may be the compensation of a drift or a displacement of a particle beam, with the repair shape being able to be adapted accordingly. During the calibration, the marking (or correction mark) usually has to be measured using a particle beam in order to determine the position of said marking, as a result of which the marking (or correction mark) may degrade and/or be worn down (as explained above).

According to the invention, not all markings (or correction marks), as was known previously, are necessarily provided for each calibration step of the (overall) processing of the mask (or the corresponding work region of the mask). The produced arrangement of groups of correction marks allows a targeted selection of desired correction marks for calibration (e.g., for the calibration when repairing a defect in a work region of the mask, which is for example calibratable by use of the markings). In this case, a boundary condition for the calibration could be that at least one correction mark from each group is used. Accordingly, for the purposes of a calibration, it is possible to choose from a set of correction marks such that the calibration steps are not limited to a single sequence tuple of correction marks. According to FIG. 5A, a multiplicity of possible sequence tuples arise with the specified boundary condition (four sequence tuples are listed in exemplary fashion): A1,A2,A3,A4; A1,B2,C3,C4; B1,A2,C3,A4; B1,A2,A3,A4; . . . ). In more general terms, it is thus possible to choose from a multiplicity of different tuples T1, T2, . . . . Tm for a calibration.

According to the invention, the selection of sequence tuples allows the minimization or distribution of the degradation of the correction marks during the processing. By way of example, different sequence tuples can be used for the calibration steps during the course of the processing. In the process, the degradation can be minimized according to a plurality of principles.

Firstly, a statistical distribution of the use of the sequence tuples is conceivable. By way of example, a fixed number of sequence tuples (e.g., three tuples: T1, T2, T3) may be available. To ensure a uniform distribution, the sequence tuples can be used cyclically over the calibration steps in one variant. For example, it is conceivable for an order of sequence tuples to be reused periodically. In the case of three sequence tuples, the choice of the sequence tuples over a plurality of calibration steps may look like the following here: T1-T2-T3-T1-T2-T3-T1-T2-T3 . . . , as a result of which each sequence tuple is stressed approximately to the same extent over the processing. Further, it is likewise conceivable for a randomized order of sequence tuples to be selected. In this context, this type of order may be mathematically based on a uniform distribution such that the used sequence tuples have been used approximately to the same extent after a multiplicity of calibration steps.

Further, it is conceivable for a sequence tuple to always be used successively until there is a change to a different sequence tuple. Firstly, this may also be designed such that there is a statistical uniform distribution of the use of the sequence tuples. In this case, the number of expected measurements (or calibration steps) during the processing of the mask can be estimated. By way of example, it may be estimated that nine calibration steps are required for the processing in one example. Therefore, in the case of three sequence tuples for example, the following order could be chosen in the calibration steps: T1-T1-T1-T2-T2-T2-T3-T3-T3, such that a uniform distribution of use of the sequence tuples is ensured.

Secondly, it is conceivable that a sequence tuple is successively used until a significant degree of wear occurs on a correction mark of the sequence tuple. Once that significant degree of wear has occurred, there can be a change to a different sequence tuple in the next calibration step. By way of example, the significant degree of wear can be ascertained by way of an assessment of a quality criterion for a correction mark of a sequence tuple (wherein a scanning electron image recording, for example, has to be made to this end). In an example, all correction marks of a sequence tuple can be assessed in relation to the quality criterion. By way of example, the quality criterion could be a contrast of the correction mark, for example. By way of example, this could also be the difference in contrast between a correction mark and its immediate surroundings. In this case, a trigger which activates a change in the sequence tuple in the next calibration step can be prompted in the case of a contrast that is too strong or too weak. Further, the quality criterion could be the assessment of a gradient image of a correction mark. By way of example, should it be gathered from the gradient image that the edges of a correction mark are significantly degraded, it is possible to prompt a trigger which activates a change of the sequence tuple in the next calibration step. Further, it is also possible to analyze the nature of the autocorrelation function of the image of the correction mark. In this case, a threshold for prompting a trigger for a sequence tuple change could be the width of the autocorrelation function, which for example could also provide information about the state of the edges of a correction mark. Further, it is also possible to analyze the nature of the cross-correlation function of the images of the correction mark at two different times. Consequently, it is possible to analytically assess the correspondence of the images, wherein a measure for the similarity of the images of the correction mark (at different times) can be determined. By way of example, if the measure for the similarity of the images (at different times) exceeds a threshold, it is possible to prompt a trigger to bring about a sequence tuple change. Further, it is also possible to analyze the nature of the cross-correlation function of the images of different correction marks. By way of example, there may be a cross-correlation between a correction mark of the sequence tuple with a correction mark of the same sequence tuple. Further, there could also be a cross-correlation between a correction mark of the sequence tuple with a correction mark not comprised in the (current) sequence tuple (for example, this latter correction mark could be from a sequence tuple which has already been used for a calibration, or from a sequence tuple which has not yet been used for a calibration). A combination of autocorrelation and cross-correlation functions of one or more correction marks can also be used for the assessment of the quality criterion. Further, the quality criterion of a correction mark or the degree of wear of a correction mark can be estimated. By way of example, this estimate may be based on the number of calibration steps for which a correction mark has already been used during processing. By way of example, on the basis of the utilized process (e.g., an electron beam induced deposition process), it is possible to estimate that a significant degradation of a correction mark can be expected, for example, after the correction mark has been read out ten times (i.e., in the case of ten calibration steps), and so there should be a change to a different sequence tuple. By way of example, this estimate may be based on empirical values and/or experiments.

FIG. 5B shows a selection of sequence tuples for an operation. In particular, three sequence tuples P1, P2, P3 are depicted. In relation to FIG. 5A, P1 in this case is given by the correction marks A1, A2, A3, A4 (with the reference signs of the correction marks not being depicted in FIG. 5B). In this case, P2 is given by the correction marks A1, C2, A3, B4. In this case, P3 is given by A1, A2, A3, A4. The connecting lines between the correction marks of the groups are presented using dashed lines for each sequence tuple, with the connecting lines of a correction mark from the second group to a correction mark from the fourth group being labelled in more detail (501, 502, 503). According to the invention, the correction marks can be placed in such a way that the work region is located within a polygon (e.g., within a triangle, trapezium, rectangle, pentagon, etc.) which is spanned by the sequence tuples. By way of example, the correction marks can be arranged in such a way that their convex sleeve defines the work region (or comprises the latter). In this case, this can be implemented in such a way that the work region is completely enclosed by the connecting lines and no connecting line of a sequence tuple intersects the work region. Consequently, it is the case that a calibration window (which is spanned by way of the correction marks of a sequence tuple) completely surrounds the envelope or contour of the work region 500. Hence, the entire work region, or the distortion of the particle beam in relation to the work region, can be interpolated over the calibration window. By way of example, the calibration window can be used for a distortion compensation which is able to measure and compensate the displacement of the particle beam, also as a first order aberration. By way of example, these circumstances are given for the sequence tuples P1 and P2 in FIG. 5B, but not for the sequence tuple P3. In the sequence tuple P3, the connecting line 503 from correction mark A4 to correction mark A2 intersects the work region 500, and so an intersection 533 is located outside of the calibration window. By way of example, the accuracy of the edge position (e.g., of the defect) may be reduced since the distortion compensation (which is carried out by way of the calibration window) implements an extrapolation in this case. During the processing of the work region (e.g., the defect), this may lead to the edge (or contour) of the work region (e.g., the defect) not being optimally traversed by the electron beam (e.g., not along the desired trajectory). These circumstances may further amplify measurement errors when determining the mark positions. Therefore, the production of correction marks in the style of the sequence tuple P3 can be avoided. Should such a sequence tuple nevertheless be produced (e.g., on account of manufacturing variations), this type of sequence tuple can preferably be precluded by a calibration method or be excluded from forming a calibration window. Alternatively, a mark from one group can be selected on the basis of the chosen mark from another group such that this type of sequence tuple is precluded.

FIG. 5C illustrates the topic of the transformation of particle beam parameters in the present invention. The aforementioned four groups of correction marks, which are for example applied to a mask, are depicted (in a manner analogous to FIG. 5A and FIG. 5B). Masks may be electrostatically charged during the irradiation with a particle beam (e.g., an electron beam). These charging phenomena have, inter alia, non-linear effects on the particle beam, and so there are effects on the trajectory of the particle beam when changing sequence tuples during the process if there is no technical adaptation. By way of example, FIG. 5C presents corresponding trajectories which are associated with the sequence tuples. Without an additional intervention, these particle beam trajectories would be traversed during the calibration. In this case, the trajectory 510 is associated with the sequence tuple C1, C2, C3, C4, with the trajectory 520 being associated with the sequence tuple B1, B2, B3, B4. Further, the trajectory 530 is associated with the sequence tuple A1, A2, A3, A4.

These effects do not necessarily lead to a significant offset of the particle beam (as is depicted schematically in FIG. 5C). However, the quality of the edges of the etched or deposited structures in the operation may deteriorate since the edges of the work region 500 are not traversed identically by the particle beam, as is presented schematically by way of the trajectories 510, 520, 530. By way of example, this may become noticeable by way of flatter side wall angles of the structures. This phenomenon can be addressed by virtue of determining a mathematical transformation for each sequence tuple, which mathematical transformation compensates the difference between the sequence tuples. This transformation may additionally be considered during the calibration (e.g., in addition to the distortion compensation of the repair shape). Consequently, it is possible to ensure that the trajectory of the particle beam remains the same, even in the case of the calibration with different sequence tuples. Initially, the global positions of all correction marks of the sequence tuples and/or the relative (initial) positions of all correction marks in relation to one another can be determined for establishing the transformation. Additionally, it is possible to determine corresponding positions of characteristic mask structures. The relative positions can be specified in terms of the vector, for example by way of a x- and y-distance (e.g., by way of an <x,y> distance vector).

The transformation can subsequently be determined in a number of ways, for example by determining the relative position of a sequence tuple X and a sequence tuple Y. By way of example, it may be known that the sequence tuple Y initially has a vectorial separation from the sequence tuple X of V1=<50 nm, 0 nm> (e.g., defined by a separation between (two or more) corresponding marks of the tuples). Initially, only the sequence tuple X may be used within the scope of the method. However, when changing from the sequence tuple X to the sequence tuple Y during the course of the method, it may turn out that the sequence tuple Y now has a vectorial separation from the sequence tuple X of V2=<100 nm, 10 nm>. This information can be used for the transformation so that the particle beam can be adapted accordingly in order to bring about a constant trajectory (in order to compensate the apparently changed separation).

By way of example, the transformation can also be established by establishing the position of the (characteristic) mask structures relative to the sequence tuple X and the sequence tuple Y. Initially, only the sequence tuple X may be used within the scope of the method. Initially, the separation of the (characteristic) mask structure from the sequence tuple X may be given by V3=<500 nm, 500 nm> and from the sequence tuple Y may be given by V4=<550 nm, 500 nm>. However, when changing from the sequence tuple X to the sequence tuple Y during the course of the method, it may turn out that now, for example, V3=<600 nm, 400 nm> and V4=<700 nm, 350 nm>. This information can be used for the transformation so that the particle beam can be adapted accordingly in order to bring about a constant trajectory.

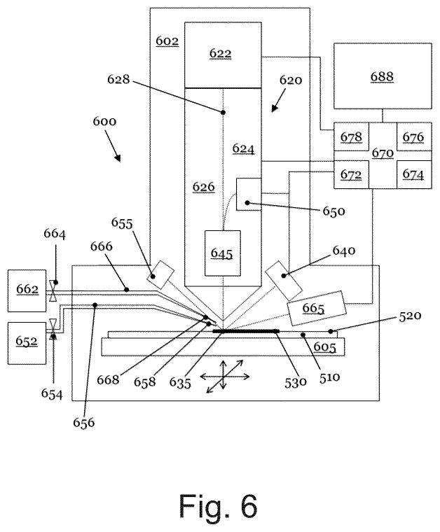

FIG. 6 schematically shows, in section, a few components of an apparatus 600, on which embodiments of the method according to the invention for examining and/or processing a mask (or generally one of the objects mentioned in the introductory part, for which the present invention can be used) can take place and be implemented. By way of example, reference is made in FIG. 6 and the description that will now follow to the mask 510 of FIGS. 5A-5C, although this is not to be understood in a limiting manner. Other lithographic masks or objects can be used instead.

The apparatus 600 comprises a vacuum chamber 602 and, therein, a scanning particle microscope 620. In the example of FIG. 6, the scanning particle microscope 620 is a scanning electron microscope (SEM) 620. An electron beam as a particle beam has the advantage that the mask 510 to be examined or processed substantially cannot be damaged, or can be damaged only to a slight extent, by said beam. However, other charged particle beams are also possible, for instance an ion beam of an FIB (focused ion beam) system (not illustrated in FIG. 6).

The SEM 620 comprises as essential components a particle gun 622 and a column 624, in which the electron optical unit or beam optical unit 626 is arranged. The electron gun 622 produces an electron beam 628 and the electron or beam optical unit 626 focuses the electron beam 628 and directs it at the output of the column 624 onto the mask 510 (or generally at a lithographic sample or object). The mask 510 has a surface 520 with a structure or structures 530, as was already explained in detail above. A surface charge that may be present on the mask 510 is not illustrated in FIG. 6.

The mask 510 is arranged on a sample stage 605. As symbolized by the arrows in FIG. 6, the sample stage 605 can be moved in three spatial directions relative to the electron beam 628 of the SEM 620.

A spectrometer-detector combination 640 discriminates the secondary electrons generated by the electron beam 628 at the measurement point 635 and/or electrons back-scattered by the mask 510 on the basis of their energy and then converts them into an electrical measurement signal. The measurement signal is then passed on to an evaluation unit 676 of the computer system 670.

To separate energy, the spectrometer-detector combination 640 can contain a filter or a filter system in order to discriminate the electrons in the energy (not illustrated in FIG. 6). Like the spectrometer-detector combination 640, energy-resolving spectrometers can be arranged outside the column 624 of the SEM 620. However, it is also possible to arrange a spectrometer and the associated detector in the column 624 of an SEM 620. In the example illustrated in FIG. 6, a spectrometer 645 and a detector 650 are incorporated in the column 624 of an SEM 620. In addition or as an alternative to the spectrometer-detector combination 640, the spectrometer 645 and the detector 650 can be used in the apparatus 600.

Furthermore, the apparatus 600 in FIG. 6 can optionally comprise a detector 655 for detecting the photons generated by the incident electron beam 628 at the measurement point 635. The detector 655 can for example spectrally resolve the energy spectrum of the generated photons and thereby allow conclusions to be drawn concerning the composition of the surface 520 or layers near the surface of the mask 510.

In addition, the apparatus 600 can comprise an ion source (not illustrated), which provides low-energy ions in the region of the measurement point 635 for the event that the mask 510 or its surface 520 is electrically insulating or semiconducting and has a negative surface charge. With the aid of the ion source, a negative charging of the mask surface 520 can be reduced locally and in a controlled manner.

Should the mask surface 520 have an undesired distribution of positive surface charges, caused for instance by the handling of the mask 510, the electron beam 628 can be used to reduce the charge of the mask surface 520.

The computer system 670 comprises a scanning unit 672, which scans the electron beam 628 over the mask 510 and in particular over the markings 540, 580 and/or the defect 550. The scanning unit 672 controls deflection elements in the column 624 of the SEM 620, which are not illustrated in FIG. 6. Furthermore, the computer system 670 comprises a setting unit 674 in order to set and control the various parameters of the SEM 620. Parameters that are settable by the setting unit 674 can be for example: the magnification, the focus of the electron beam 628, one or more settings of the stigmator, the beam displacement, the position of the electron source and/or one or more stops (not illustrated in FIG. 6).

The scanning unit 672 and/or the setting unit 674 can perform or control or contribute to for example an examination and/or processing of the mask 510 in the work region 560 with the use of an embodiment of a method according to the invention.

Moreover, the computer system 670 comprises a memory unit 676, in which for example instructions for performing an embodiment of one of the methods according to the invention can be stored. The computer system 670 can comprise one or more processors which are designed to implement such instructions, that is to say to control and activate the corresponding components of the apparatus 600 (for example the SEM 620, the scanning unit 672, the setting unit 674 and/or the gas feed system yet to be described) in accordance with the commands. The processor can comprise a powerful graphics processor, for example.

The computer system 670 in FIG. 6 can be integrated into the apparatus 600 or it can be in the form of dedicated equipment. The computer system 670 can be embodied using hardware, software, firmware or a combination.

For processing the defect 550 of the mask 510 and/or for writing (first and/or second) reference markings 540 and/or 580 onto the mask 510, the apparatus 600 of FIG. 6 preferably has a plurality of different storage containers for different process or precursor gases. In the apparatus 600 given by way of example, two storage containers are illustrated. However, an apparatus 600 can also have more than two storage containers for processing the mask 510 and/or writing reference markings 540, 580 onto the mask 510. The first storage container 652 stores a precursor gas or a deposition gas, which can be used to act together with the electron beam 628 of the SEM 620 for depositing material for example for producing a reference marking 540, 580 of the mask 510. Moreover, the electron beam 628 of the SEM 620 can be used for example for depositing missing absorber material of one of the pattern elements of the mask 510. The second storage container 662 contains an etching gas, with the aid of which the defect 550 can be etched, for example.

Each storage container 652, 662 is equipped with its own valve 654 and 664, respectively, to control the amount of gas particles provided per unit time or the gas flow rate at the location of incidence 635 of the electron beam 628 on the surface 520 of the mask 510. Furthermore, the two storage containers 652, 662 have their own gas feeds 656, 666, which end with a nozzle 658, 668 near the point of incidence 635 of the electron beam 628 on the mask 510. In the apparatus 600 that is illustrated by way of example in FIG. 6, the valves 654, 664 are incorporated in the vicinity of the storage containers. In an alternative embodiment, the valves 654, 664 can be arranged in the vicinity of the corresponding nozzle 658 and 668, respectively (not shown in FIG. 6). Each storage container 652, 662 can have its own element for individual temperature setting and control. Setting the temperature allows each precursor gas to be both cooled and heated. In addition, the gas feeds 656, 666 can likewise respectively have their own element for setting and monitoring the temperature at which each precursor gas is provided at the reaction location (likewise not shown in FIG. 6).

The apparatus 600 in FIG. 6 can comprise a pump system to produce and maintain the required vacuum. The pump system is not shown in FIG. 6 for reasons of clarity. In addition, the apparatus 600 can comprise a suction extraction apparatus (likewise not illustrated in FIG. 6). The suction extraction apparatus in combination with a pump or a pump system makes it possible that the fragments or constituents that are produced during the decomposition of a precursor gas and are not required for the local chemical reaction are extracted from the vacuum chamber 602 of the apparatus 600 substantially at the point of origin. Since the gas constituents that are not required are pumped away locally at the location of incidence of the electron beam 628 on the mask 510 out of the vacuum chamber 602 of the apparatus 600 before they can be distributed and settle in it, contamination of the vacuum chamber 602 is prevented.

In the following further embodiments of the invention are described.

An embodiment 1 relates to a method for producing correction marks on an object for lithography, in particular for calibrating an operation, using a particle beam, including:
a. producing a first group (A1, B1, C1) of correction marks;
b. producing a second group (A2, B2, C2) of correction marks;
c. wherein the separations of the correction marks within the first and within the second group are smaller than the separations between correction marks from the first group and correction marks from the second group.

Embodiment 2: A method according to embodiment 1, wherein the first group and/or the second group comprise correction marks with at least partly the same form.

Embodiment 3: A method according to either of embodiments 1-2, wherein at least one correction mark from the first group and/or the second group is composed of a plurality of geometric shapes.

Embodiment 4: A method according to any one of embodiments 1-3, wherein the number of correction marks from the first group and/or the second group is at least three, preferably at least four.

Embodiment 5: A method according to any one of embodiments 1-4, wherein the separations of the correction marks within the first and/or within the second group are at least five times smaller, preferably at least ten times smaller, particularly preferably at least twenty times smaller than the separations between correction marks from the first group and correction marks from the second group.

Embodiment 6: A method according to any one of embodiments 1-5, wherein the production is at least partially based on a particle beam induced deposition process and/or a particle beam induced etching process.

Embodiment 7: A method according to any one of embodiments 1-6, further comprising: producing at least one third group (A3, B3, C3) of correction marks, the separations of the correction marks within the individual groups being smaller than the separations spanned between correction marks from two different groups.

Embodiment 8: A method according to embodiment 7, wherein the produced groups surround a work region (500) of an operation in such a way that connecting lines between in each case two correction marks of different groups are able to surround the work region without intersecting the work region.

An embodiment 9 relates to a method for calibrating an operation on an object for lithography with the aid of at least one local group (A1, B1, C1; A2, B2, C2) of spaced apart correction marks using a particle beam, the method including the following sequence:
S1. selecting a sequence tuple (A1; A2), the sequence tuple comprising a subset of correction marks of the at least one group;
S2. carrying out a calibration, at least partially based on the sequence tuple (A1; A2);
S3. carrying out at least a part of the operation, at least partially based on the carried out calibration.

Embodiment 10: A method according to embodiment 9, wherein the selection of the sequence tuple is at least partially based on an assessment of a predetermined criterion which is associated with at least one correction mark of the at least one group.

Embodiment 11: A method according to embodiment 10, wherein the predetermined criterion comprises at least one of the following criteria: a degree of wear of the at least one correction mark, a contrast of the at least one correction mark, a gradient image of the at least one correction mark, an autocorrelation function of an image of the at least one correction mark, a cross-correlation function of at least two images of the at least one correction mark.

Embodiment 12: A method according to any one of embodiments 9-11, wherein the sequence is repeated at least once and, in the process, at least two sequence tuples are selected, the sequence tuples comprising differing subsets of correction marks.

Embodiment 13: A method according to any one of embodiments 9-12, wherein the sequence tuple is selected in such a way that it comprises a subset of correction marks from each of at least m groups of correction marks, where m is greater than or equal to 2, and wherein the separations of the correction marks within the individual groups are smaller than the separations which are spanned between correction marks from two different groups.

Embodiment 14: A method according to embodiment 13, wherein the selection of the sequence tuple is at least partially based on a number of expected sequences during the operation.

Embodiment 15: A method according to any one of embodiments 9-14, wherein the selection of the sequence tuples over the sequences of the operation is implemented in accordance with a predetermined order.

Embodiment 16: A method according to any one of embodiments 9-15, wherein the selection is implemented in accordance with a cyclical order of sequence tuples, a randomized order of sequence tuples and/or a row of the same sequence tuples.

Embodiment 17: A method according to any one of embodiments 9-16, wherein the method further includes:
determining a transformation of particle beam parameters which is associated with two sequence tuples;
carrying out the calibration, at least partially based on the determined transformation.

Embodiment 18: A method according to embodiment 17, wherein determining the transformation comprises at least one of the following:
determining a relative position of correction marks of different sequence tuples in relation to one another;
determining the relative positions of correction marks of different sequence tuples in relation to one or more structures of the object for lithography.

Embodiment 19: A method according to any one of embodiments 1-18, wherein the calibration comprises determining a drift of the particle beam and/or correcting a drift of the particle beam.

Embodiment 20: A method according to any one of embodiments 1-19, wherein the operation comprises repairing a defect.

Embodiment 21 relates to an apparatus for producing correction marks on an object for lithography and/or calibrating an operation using a particle beam, comprising:
a. means for carrying out the method according to any one of embodiments 1-20, and
b. means for carrying out a computer program.

Embodiment 22 relates to a computer program comprising instructions which, when executed, cause the apparatus according to embodiment 21 to carry out the method steps of the method according to any one of embodiments 1-20.

Embodiment 23: an apparatus according to embodiment 21, with a memory comprising the computer program according to embodiment 22.

What is claimed is:

1. A method for calibrating an operation on an object for lithography with the aid of at least one local group of spaced apart correction marks using a particle beam, the method including the following sequence:
S1. selecting a sequence tuple, the sequence tuple comprising a subset of correction marks of the at least one group;
S2. carrying out a calibration, at least partially based on the sequence tuple; and
S3. carrying out at least a part of the operation, at least partially based on the carried out calibration;
wherein the sequence is repeated at least once and at least two sequence tuples are selected which comprise differing subsets of correction marks.

2. The method of claim 1, wherein the selecting of the sequence tuple is at least partially based on an assessment of a predetermined criterion which is associated with at least one correction mark of the at least one group.

3. The method of claim 2, wherein the predetermined criterion comprises at least one of the following criteria:
a degree of wear of the at least one correction mark, a contrast of the at least one correction mark, a gradient image of the at least one correction mark, an autocorrelation function of an image of the at least one correction mark, a cross-correlation function of at least two images of the at least one correction mark.

4. The method of claim 1, wherein the sequence tuple is selected in such a way that it comprises a subset of correction marks from each of at least m groups of correction marks, where m is greater than or equal to 2, and wherein the separations of the correction marks within the individual groups are smaller than the separations which are spanned between correction marks from two different groups.

5. The method of claim 4, wherein the selecting of the sequence tuple is at least partially based on a number of expected sequences during the operation.

6. The method of claim 1, wherein the selecting of the sequence tuples over the sequences of the operation is implemented in accordance with a predetermined order.

7. The method of claim 1, wherein the selecting is implemented in accordance with a cyclical order of sequence tuples, a randomized order of sequence tuples and/or a row of the same sequence tuples.

8. The method of claim 1, wherein the method further includes:
determining a transformation of particle beam parameters which is associated with two sequence tuples; and
carrying out the calibration, at least partially based on the determined transformation.

9. The method of claim 8, wherein determining the transformation comprises at least one of the following:
determining a relative position of correction marks of different sequence tuples in relation to one another; and
determining the relative positions of correction marks of different sequence tuples in relation to one or more structures of the object for lithography.

10. A method for producing correction marks on an object for lithography and/or calibrating an operation, using a particle beam, including:
a. producing a first group of correction marks; and
b. producing a second group of correction marks;
c. wherein the separations of the correction marks within the first and within the second group are smaller than the separations between correction marks from the first group and correction marks from the second group;
wherein the separations of the correction marks within the first and/or within the second group are at least five times smaller than the separations between correction marks from the first group and correction marks from the second group.

11. The method of claim 10, wherein the first group and/or the second group comprise correction marks with at least partly the same form.

12. The method of claim 10, wherein at least one correction mark from the first group and/or the second group is composed of a plurality of geometric shapes.

13. The method of claim 10, wherein the number of correction marks from the first group and/or the second group is at least three.

14. The method of claim 10, wherein the producing is at least partially based on a particle beam induced deposition process and/or a particle beam induced etching process.

15. The method of claim 10, further comprising:
producing at least one third group of correction marks, the separations of the correction marks within the individual groups being smaller than the separations spanned between correction marks from two different groups.

16. The method of claim 15, wherein the produced groups surround a work region of an operation in such a way that connecting lines between two correction marks of different groups are able to surround the work region without intersecting the work region.

17. The method of claim 1, wherein the calibration comprises determining a drift of the particle beam and/or correcting a drift of the particle beam.

18. The method of claim 1, wherein the operation comprises repairing a defect.

19. An apparatus for producing correction marks on an object for lithography and/or calibrating an operation using a particle beam, comprising:
a. means for carrying out the method of claim 1, and
b. means for carrying out a computer program.

20. A non-volatile computer-readable medium storing a computer program comprising instructions which, when executed, cause the apparatus of claim 19 to carry out a method for calibrating an operation on an object for lithography with the aid of at least one local group of spaced apart correction marks using a particle beam, the method including the following sequence:
S1. selecting a sequence tuple, the sequence tuple comprising a subset of correction marks of the at least one group;
S2. carrying out a calibration, at least partially based on the sequence tuple; and
S3. carrying out at least a part of the operation, at least partially based on the carried out calibration;
wherein the sequence is repeated at least once and at least two sequence tuples are selected which comprise differing subsets of correction marks.

21. The apparatus of claim 19, comprising a memory comprising a computer program comprising instructions which, when executed, cause the apparatus to carry out a method for calibrating an operation on an object for lithography with the aid of at least one local group of spaced apart correction marks using a particle beam, the method including the following sequence:
S1. selecting a sequence tuple, the sequence tuple comprising a subset of correction marks of the at least one group;
S2. carrying out a calibration, at least partially based on the sequence tuple; and
S3. carrying out at least a part of the operation, at least partially based on the carried out calibration;
wherein the sequence is repeated at least once and at least two sequence tuples are selected which comprise differing subsets of correction marks.

22. The method of claim 10, wherein the separations of the correction marks within the first and/or within the second group are at least ten times smaller than the separations between correction marks from the first group and correction marks from the second group.

23. The method of claim 10, wherein the separations of the correction marks within the first and/or within the second group are at least twenty times smaller than the separations between correction marks from the first group and correction marks from the second group.

24. The method of claim 1, wherein the at least one local group comprises a first local group (A1, B1, C1) of spaced apart correction marks and a second local group (A2, B2, C2) of spaced apart correction marks, selecting the sequence tuple comprises selecting a sequence tuple (A1; A2), and carrying out the calibration comprises carrying out the calibration at least partially based on the sequence tuple (A1; A2).

25. The method of claim 24, wherein at least one local group comprises a third local group (A3, B3, C3) of spaced apart correction marks, the separations of the correction marks within the individual groups being smaller than the separations spanned between correction marks from two different groups;
wherein selecting the sequence tuple comprises selecting a sequence tuple (A1; A2; A3), and carrying out the calibration comprises carrying out the calibration at least partially based on the sequence tuple (A1; A2; A3).
